(19) United States
(12) Patent Application Publication
(10) Pub. No.: US 2008/0304245 A1
(43) Pub. Date: Dec. 11, 2008

(54) SEMICONDUCTOR PACKAGE AND METHOD FOR DISCHARGING ELECTRONIC DEVICES ON A SUBSTRATE

(75) Inventors: Chih Ming CHOU, Kaohsiung (TW); Yu Jen Wang, Kaohsiung (TW); Chao Yung Wang, Kaohsiung City (TW); Yu Pin Lin, Kaohsiung City (TW); Chen Ping Su, Kaohsiung City (TW)

Correspondence Address: LOWE HAUPTMAN HAM & BERNER, LLP, 1700 DIAGONAL ROAD, SUITE 300, ALEXANDRIA, VA, 22314, US

(73) Assignee: ORIENT SEMICONDUCTOR ELECTRONICS, LIMITED, KAOHSIUNG (TW)

(21) Appl. No.: 11/875,611

(22) Filed: Oct. 19, 2007

(30) Foreign Application Priority Data
Jun. 8, 2007 (TW) 096120685

(51) Int. Cl. B23K 1/20; H05K 7/02

(52) U.S. Cl. 361/811; 228/176

(57) ABSTRACT

A method for discharging an electronic device on a substrate is provided. A metal pin mounted on a wire bonder is used to touch with a specific finger disposed on the substrate which is in electrical connection with the electronic device. As a result, the electric charge previously stored in the electronic device will be conducted to the wire bonder through the specific finger and metal pin thereby discharging the stored charge. Another method for discharging an electronic device on a substrate is also provided. A metal wire protruding out from the capillary of a wire bonder is heated to form a metal ball at the capillary. The capillary is moved to bring the metal ball into contact with the specific finger. As a result, the electric charge previously stored in the electronic device will thus can be discharged to the wire bonder. The present invention further provides a semiconductor package.

### CROSS REFERENCE TO RELATED APPLICATION

This application claims the priority benefit of Taiwan Patent Application Serial Number 096120685 filed Jun. 8, 2007, the full disclosure of which is incorporated herein by reference.

### BACKGROUND OF THE INVENTION

1. Field of the Invention

The invention relates to a method for discharging electronic devices, and more particularly, to a method for discharging electronic devices on a substrate. The invention also relates to a semiconductor package.

2. Description of the Related Art

According to conventional semiconductor package processes, in order to electrically connect a chip to the substrate on which the chip is mounted, a wire bonder is typically used to connect wires from the chip to the substrate. Generally, to make easy to achieve the wire bonding, one end of a bonding wire is first bonded to one of the bonding pads on the chip and the other end of the bonding wire is then bonded to the corresponding finger on the substrate. However, some devices, such as capacitors mounted to the substrate may have been fully charged prior to the wire bonding process. In the event that the charged capacitors have been in electrical connection with the corresponding finger, the charge stored in the capacitors can be conducted to the chip through the bonding wire when the wire is first bonded to the chip and then to the corresponding finger to form an electrical connection between the chip and the finger. As a result, the current resulted from the charge flow from the capacitors to the chip is likely to damage the chip.

Accordingly, there exists a need to provide a method for discharging electronic devices on a substrate to solve the above-mentioned problems.

### SUMMARY OF THE INVENTION

It is an object of the present invention to provide a method for discharging electronic devices on a substrate. Prior to wire bonding from a chip to a finger on the substrate, the charge previously stored in the electronic devices is discharged in order to prevent the current from occurring due to an electrical connection between the chip and the finger formed in the wire bonding process to damage the chip.

In one embodiment, the method for discharging electronic devices on a substrate is to provide a wire bonder with a metal pin electrically connecting to the wire bonder. When wanting to discharge an electronic device, such as capacitor on a substrate, the metal pin is brought into electrical contact with a specific finger which is in electrical connection with the electronic device. As a result, the charge previously stored in the electronic device will be conducted to the wire bonder through the specific finger and the metal pin thereby discharging the stored charge.

In another embodiment, the method for discharging electronic devices on a substrate is first to heat a metal wire protruding out from a capillary of a wire bonder to form a metal ball at the capillary. Afterward, the capillary is moved to bring the metal ball into contact with the first portion of the finger. As a result, the charge previously stored in the electronic device will be conducted to the wire bonder through the finger, the metal ball and the metal wire thereby discharging the stored charge.

The present invention further provides a semiconductor package. After the metal ball has been formed on the first portion of the finger, a metal wire is used to electrically connect the chip to the second portion of the finger. Finally, a sealant is formed on the substrate to encapsulate the chip, metal ball, metal wire, finger and electronic device.

The foregoing, as well as additional objects, features and advantages of the invention will be more readily apparent from the following detailed description, which proceeds with reference to the accompanying drawings.

### BRIEF DESCRIPTION OF THE DRAWINGS

FIG. 1 illustrates the method for discharging electronic devices on a substrate according to the first embodiment of the present invention.

FIGS. 2a and 2b illustrate the method for discharging electronic devices on a substrate according to the second embodiment of the present invention.

FIG. 2c illustrates that a metal ball is left on the finger of the substrate after the performance of the method according to the second embodiment of the present invention.

FIG. 3 is a cross-sectional view of the semiconductor package of the present invention.

### DETAILED DESCRIPTION OF THE PREFERRED EMBODIMENT

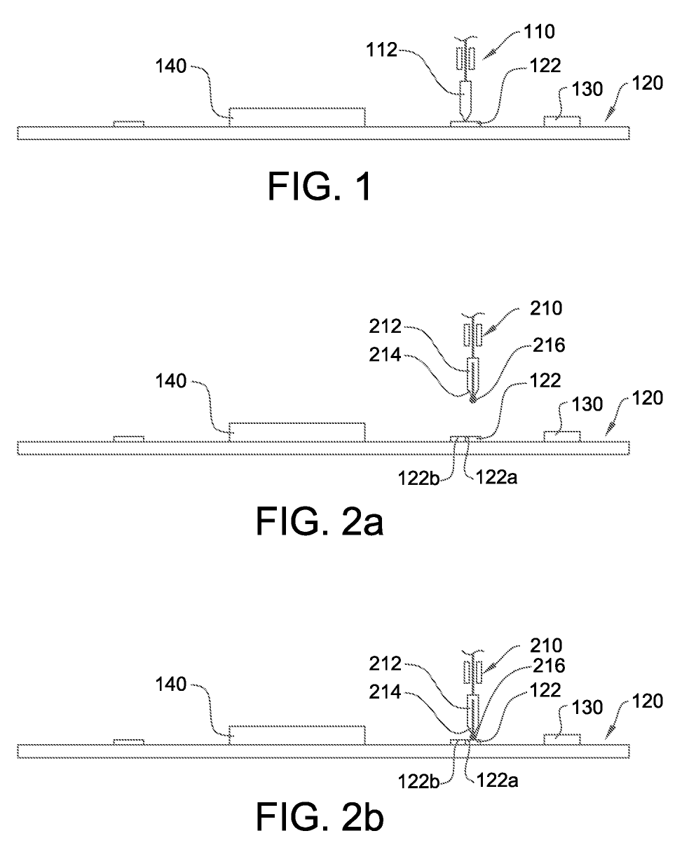

Referring to FIG. 1, the method for discharging electronic devices on a substrate according to the first embodiment of the present invention is to provide a wire bonder 110 with a metal pin 112 electrically connecting to the wire bonder 110. When wanting to discharge an electronic device 130, such as capacitor on a substrate 120, the metal pin 112 is brought into electrical contact with a specific finger 122 which is in electrical connection with the electronic device 130. As a result, the charge previously stored in the electronic device 130 will be conducted to the wire bonder 110 through the specific finger 122 and the metal pin 112 thereby discharging the stored charge.

The method described above can be performed prior to or subsequent to the attachment of a chip 140 to the substrate 120 but is required to be carried out before the wire bonding. This will prevent the current from occurring due to an electrical connection between the chip 140 and the specific finger 122 on the substrate 120 formed in the wire bonding process to damage the chip 140.

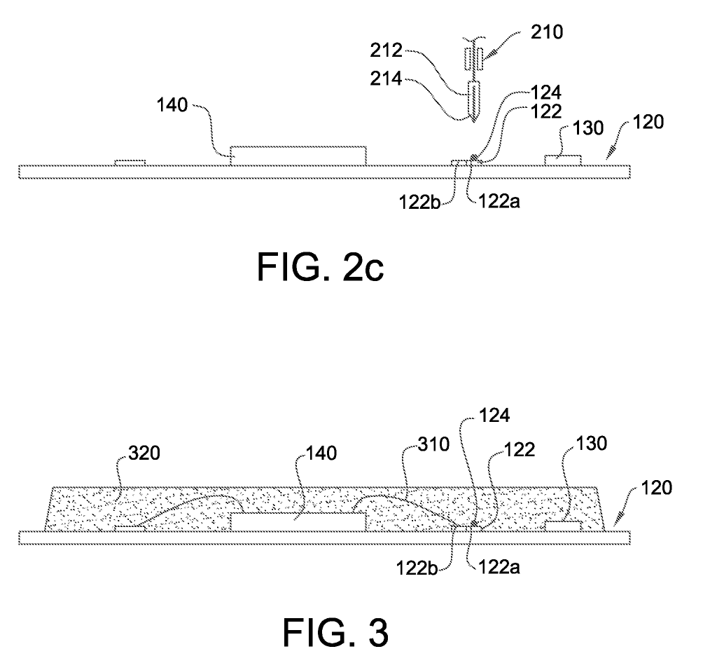

Referring to FIGS. 2a and 2b, the method for discharging electronic devices on a substrate according to the second embodiment of the present invention is first to heat a metal wire 214 protruding out from a capillary 212 of a wire bonder 210 to form a metal ball 216 at the capillary 212. Afterward, the capillary 212 is moved to bring the metal ball 216 into contact with the finger 122 at a certain portion, e.g. first portion 122a. As a result, the charge previously stored in the electronic device 130 will be conducted to the wire bonder 210 through the finger 122, the metal ball 216 and the metal wire 214 thereby discharging the stored charge.

After the charge stored in the electronic device 130 is discharged, both the original wire bonder 210 and capillary 212 can continue to be used to perform the wire bonding from the chip 140 to the finger 122 without need to change the wire bonder 210 and capillary 212. Accordingly, the time for changing these wire-bonding facilities can be saved. Furthermore, referring to FIG. 2c, after the capillary 212 is moved from the finger 122, the metal ball 216 will be secured to the finger 122 to form a metal ball 124. At this stage, there is no need to remove the metal ball 124 from the finger 122 in order to proceed with the wire bonding from the chip 140 to the finger 122. It just needs to wire bond the chip 140 to the finger 122 at other portion different from the first portion 122a, e.g. second portion 122b. Besides, according to the method for discharging electronic devices on a substrate of the second embodiment of the present invention, the metal wire 214 is not required to be heated to form the metal ball 216 at the capillary 212 in order to come into contact with the finger 122 to discharge the charge stored in the electronic device 130. It just needs to bring the metal wire 214 directly into electrical contact with the finger 122.

Referring to FIG. 3, the present invention further provides a semiconductor package 300. After the metal ball 124 is formed on the first portion 122a of the finger 122 on the substrate 120, a metal wire 310 is used to electrically connect the chip 140 to the second portion 122b of the finger 122. Finally, a sealant 320 is formed on the substrate 120 to encapsulate the chip 140, metal ball 124, metal wire 310, finger 122 and electronic device 130. The semiconductor package 300 of the present invention is similar to a conventional one in structure. The substrate 120 of the semiconductor package 300 also has a portion exposed out of the sealant 320 on which is provided with output terminals for electrically connecting to other electronic devices (not shown in the figure). The output terminals can be common gold fingers, leaders or solder balls. Because these output terminals are well-known in the art, any further illustrations of these elements will be omitted herein.

Although the preferred embodiments of the invention have been disclosed for illustrative purposes, those skilled in the art will appreciate that various modifications, additions and substitutions are possible, without departing from the scope and spirit of the invention as disclosed in the accompanying claims.

What is claimed is:

1. A method for discharging an electronic device on a substrate, the substrate having a finger thereon which is electrically connected to the electronic device, the method comprising the steps of:
providing a wire bonder having a metal pin electrically connecting to the wire bonder; and
bringing the metal pin into electrical contact with the finger on the substrate so that the charge previously stored in the electronic device can be conducted to the wire bonder through the finger and the metal pin thereby discharging the stored charge.

2. The method as claimed in claim 1, wherein the electronic device is a capacitor.

3. A method for discharging an electronic device on a substrate, the substrate having a finger thereon which is electrically connected to the electronic device, the method comprising the steps of:
providing a wire bonder having a capillary and a metal wire protruding out from the capillary; and
bringing the metal wire protruding out from the capillary into electrical contact with the finger so that the charge previously stored in the electronic device can be conducted to the wire bonder through the finger and the metal wire thereby discharging the stored charge.

4. The method as claimed in claim 3, wherein the step of bringing the metal wire into electrical contact with the finger comprising:
heating the metal wire protruding out from the capillary to form a metal ball at the capillary; and
bringing the metal ball into electrical contact with the finger.

5. The method as claimed in claim 3, wherein the electronic device is a capacitor.

6. The method as claimed in claim 4, wherein the electronic device is a capacitor.

7. A semiconductor package, comprising:
a substrate;
a chip disposed on the substrate;
an electronic device disposed on the substrate;
a finger disposed on the substrate and electrically connected to the electronic device, the finger having a first portion and a second portion;
a metal ball formed on the first portion of the finger;
a metal wire electrically connecting the chip to the second portion of the finger; and
a sealant formed on the substrate and encapsulating the chip, metal ball, metal wire, finger and electronic device.

8. The semiconductor package as claimed in claim 7, wherein the metal ball is formed by the steps comprising:
heating a metal wire protruding out from a capillary of a wire bonder to form a metal ball at the capillary;
bringing the metal ball into contact with the finger; and
separating the metal wire protruding out from the capillary from the metal ball on the finger.

9. The semiconductor package as claimed in claim 7, wherein the electronic device is a capacitor.

10. The semiconductor package as claimed in claim 8, wherein the electronic device is a capacitor.
